(19) United States
(12) Patent Application Publication
(10) Pub. No.: US 2013/0095660 A1
(43) Pub. Date: Apr. 18, 2013

(54) METHOD FOR POLISHING SILICON WAFER

(71) Applicants: Ryuichi Tanimoto, Tokyo (JP); Shinya Sadohara, Tokyo (JP); Takeru Takushima, Tokyo (JP)

(72) Inventors: Ryuichi Tanimoto, Tokyo (JP); Shinya Sadohara, Tokyo (JP); Takeru Takushima, Tokyo (JP)

(73) Assignee: SUMCO CORPORATION, Tokyo (JP)

(21) Appl. No.: 13/807,082

(22) PCT Filed: Jul. 1, 2011
(86) PCT No.: PCT/JP2011/065145

§ 371 Date: Dec. 27, 2012

(30) Foreign Application Priority Data
Jul. 2, 2010 (JP) 2010-152088

(51) Int. Cl. H01L 21/306

(52) U.S. Cl. CPC H01L 21/30625
USPC 438/692

(57) ABSTRACT

To final polish a finish-polished surface using a final polishing solution whose chief component is a weakly basic aqueous solution that does not contain abrasive grains. During the final polishing, the weakly basic aqueous solution having an alkali concentration that reduces a haze value of a final-polished surface below the haze value of the finish-polished surface of the wafer is used as the chief component of the final polishing solution.

### FIELD OF THE INVENTION

The present invention relates to a method for polishing a silicon wafer. More specifically, the present invention relates to a method for polishing a silicon wafer in which the silicon wafer and a polishing cloth are rotated relative to each other while a polishing solution is supplied to polish at least a front surface of the front and rear surfaces of the silicon wafer as a polished surface.

### BACKGROUND OF THE INVENTION

In recent years, CMP (chemical-mechanical polishing) has been common as a method for polishing a front surface of a silicon wafer. CMP is performed by rotating the silicon wafer and a polishing cloth relative to each other while supplying a polishing solution, in which an alkaline aqueous solution contains free abrasive grains such as silica grains. CMP is known for obtaining a high degree of flatness for a front surface of the silicon wafer by combining a mechanical polishing effect from the free abrasive grains with a chemical polishing effect from the alkaline aqueous solution. In the CMP process, typically, the front surface of the wafer is polished through a plurality of steps, from rough polishing to finish polishing. Rough polishing, the earliest step, seeks to polish the silicon wafer to a desired thickness. A hard polishing cloth such as polyurethane is used with a comparatively high polishing speed to polish the silicon wafer so as to reduce and flatten variations in the thickness of the silicon wafer after polishing. In the rough polishing operation, the polishing process may be performed while dividing the polishing amount (stock) of the silicon wafer into a plurality of stages (e.g., one to three stages) and changing the type of polishing cloth and the size of the free abrasive grains.

Finish polishing is performed to remedy roughness on the front surface of the silicon wafer. A pliant polishing cloth such as suede is used with minute free abrasive grains to polish the silicon wafer so as to reduce minute variations in surface roughness (called a “haze”) on the front surface of the wafer. In some cases, similar to the rough polishing operation, the finish polishing operation may be divided into a plurality of stages while changing the type of polishing cloth and the size of the free abrasive grains. However, when the finish polishing is performed using a polishing solution (slurry) containing free abrasive grains, roughness of the front surface of the wafer can be remedied to a certain extent. Nevertheless, micro-scratches (processing-induced defects) develop in the front surface of the silicon wafer, caused by an aggregation of free abrasive grains in the polishing solution.

Meanwhile, Related Art 1 suggests that after finish polishing that includes a polishing material (abrasive grains), a chemical polishing solution not containing the polishing material be supplied to the polishing cloth while polishing the wafer until hidden blemishes (micro-scratches and the like) that have developed from the finish polishing with the free abrasive grains are no longer present. Specifically, Related Art 1 reports that for a wafer which has been finish polished using slurry that contains free abrasive grains, scratch artifacts are mostly eliminated by polishing the front surface of the wafer for approximately 30 minutes with 0.2% by weight of NaOH aqueous solution that does not contain free abrasive grains so as to strip the front surface of the wafer to a depth of 5 μm.

### RELATED ART

### Patent Literature

Related Art 1: Japanese Patent Laid-open Publication No. 3202305

### SUMMARY OF THE INVENTION

### Problems to Be Solved by the Invention

However, when a chemical polishing solution that does not contain free abrasive grains is used after finish polishing to polish the front surface of the silicon wafer until the hidden blemishes are no longer present, as recited in Related Art 1, a phenomenon may develop in which the front surface of the wafer undergoes isotropic etching and a haze level on the front surface of the silicon wafer deteriorates as compared to a silicon wafer after finish polishing with free abrasive grains.

The present invention has as an object to provide a method for polishing a silicon wafer capable of improving a haze level on a front surface of the silicon wafer.

When conducting finish polishing, which is generally performed using a polishing solution that contains free abrasive grains, the haze level on the front surface of the silicon wafer obtained by rough polishing can be improved to a certain degree. However, the haze level on the front surface of the silicon wafer after finish polishing using free abrasive grains is greatly dependent on an average particle size of the free abrasive grains used. The more minute the abrasive grains used, the more improvement can be attained in the haze level. However, when the average particle size of the abrasive grains is reduced, the dispersability of the abrasive grains within the polishing solution decreases and the abrasive grains aggregate, which may cause processing-induced defects such as scratches in the front surface of the silicon wafer. Therefore, in the finish polishing that employs the polishing solution containing free abrasive grains, the polishing can only be performed within a range of average particle size that does not lead to aggregation of the abrasive grains. There is thus a limitation on the haze level that can be remedied by finish polishing.

In order to resolve the above-described circumstances for the haze level in finish polishing, the inventors of the present invention have achieved the present invention based on the results of thorough research and the below findings, while conceiving that by polishing (final polishing) using a polishing solution chiefly composed of a weakly basic aqueous solution that does not contain free abrasive grains, selective etching removes protrusions in unevenness, which are components of haze on the front surface of the silicon wafer after finish polishing. Specifically, the inventors of the present invention have discovered that the haze level which can be achieved by final polishing without free abrasive grains is dependent on the type and concentration of alkali in the chemical polishing solution, and that using a low alkali concentration can reduce the haze value, thus achieving the present invention.

### Means for Solving the Problems

The invention according to claim 1 is a method for polishing a silicon wafer in which a polishing cloth and the silicon wafer are rotated relative to each other while a finish polishing solution containing free abrasive grains is supplied to the polishing cloth to finish polish at least a front surface of the front and rear surfaces of the silicon wafer. Then, after the finish polishing, the polishing cloth and the silicon wafer are rotated relative to each other while a final polishing solution chiefly composed of a weakly basic aqueous solution not containing free abrasive grains is supplied to the polishing cloth to final polish a surface of the silicon wafer that has been finish polished. The method for polishing the silicon wafer adjusts an alkali concentration of the weakly basic aqueous solution in the final polishing solution such that a haze value of the final-polished surface of the silicon wafer is lower than the haze value of the finish-polished surface of the silicon wafer.

The invention according to claim 2 is the method for polishing the silicon wafer according to claim 1, in which the alkali concentration of the weakly basic aqueous solution in the final polishing solution is 0.1 to 1000 ppm when the weakly basic aqueous solution is ammonia water; 0.1 to 100 ppm when the weakly basic aqueous solution is an aqueous solution of tetramethylammonium hydroxide; and 0.1 to 500 ppm when the weakly basic aqueous solution is a mixed aqueous solution of ammonia and ammonium bicarbonate.

The invention according to claim 3 is the method for polishing the silicon wafer according to one of claims 1 and 2, in which a water-soluble polymer is added to the final polishing solution.

The invention according to claim 4 is the method for polishing the silicon wafer according to claim 3, in which the water-soluble polymer is one kind or several kinds among a non-ionic polymer and a monomer, or one kind or several kinds among an anionic polymer and a monomer.

The invention according to claim 5 is the method for polishing the silicon wafer according to claim 4, in which the water-soluble polymer is hydroxyethylcellulose.

The invention according to claim 6 is the method for polishing the silicon wafer according to claim 1, in which the polishing cloth used in the final polishing is of a suede type.

### EFFECT OF THE INVENTION

According to the method for polishing the silicon wafer of the present invention, during final polishing of the silicon wafer, the alkali concentration of the weakly basic aqueous solution is made to be less than the alkali concentration at which the haze value of the finish-polished surface of the silicon wafer would be reached. Therefore, the haze level on the final-polished surface of the silicon wafer can be made to not deteriorate further than the haze level on the finish-polished surface due to an alkali etching action of the final polishing solution, which is chiefly composed of the weakly basic aqueous solution not containing free abrasive grains.

When the water-soluble polymer is added to the final polishing solution, the haze level can be further improved.

### BRIEF DESCRIPTION OF THE DRAWINGS

FIG. 1 is a flowchart illustrating a method for polishing a silicon wafer in a first embodiment according to the present invention.

FIG. 2 is a front view of a single surface mirror polishing device used in the method for polishing the silicon wafer in the first embodiment according to the present invention.

FIG. 3 is a graph describing a relationship between an additive rate of an alkaline agent (differentiated by type) in a final polishing solution and a haze level in the method for polishing the silicon wafer in the first to third embodiments according to the present invention.

FIG. 4 is a graph describing a relationship between an additive rate of hydroxyethyl cellulose in the final polishing solution and the haze level in the method for polishing the silicon wafer in the first embodiment according to the present invention.

FIGS. 5(a) to 5(c) are expanded cross-sectional views of a relevant portion of a silicon wafer illustrating a change in a haze level at different stages of polishing with abrasive grains in a conventional method for polishing the silicon wafer.

FIGS. 6(a) to 6(c) are expanded cross-sectional views of a relevant portion of the silicon wafer illustrating a change in the haze level over time when polishing without abrasive grains in the method for polishing the silicon wafer according to the present invention.

### MODE FOR CARRYING OUT THE INVENTION

Hereafter, an embodiment of the present invention is specifically described.

In a method for polishing a silicon wafer in the present invention, a polishing cloth and the silicon wafer are rotated relative to each other while a finish polishing solution containing free abrasive grains is supplied to the polishing cloth to finish polish at least a front surface of the front and rear surfaces of the silicon wafer. Then, after the finish polishing, the polishing cloth and the silicon wafer are rotated relative to each other while a final polishing solution chiefly composed of a weakly basic aqueous solution not containing free abrasive grains is supplied to the polishing cloth to final polish the finish-polished surface of the silicon wafer. The method for polishing the silicon wafer adjusts an alkali concentration of the weakly basic aqueous solution in the final polishing solution such that a haze value of the final-polished surface of the silicon wafer is lower than the haze value of the finish-polished surface of the silicon wafer.

Herein, a detailed description is given for a manner in which the haze level on the finish-polished front surface of the silicon wafer can be remedied with the method for polishing the silicon wafer in the present invention. In the method for polishing the silicon wafer in the present invention, the final polishing solution does not contain free abrasive grains. Therefore, processing-induced defects due to an aggregation of free abrasive grains do not develop and the present invention is not subject to haze level constraints due to limitations on the usable size of abrasive grains. A particularly essential feature in the method for polishing the silicon wafer in the present invention is using a polishing solution chiefly composed of the weakly basic aqueous solution as the final polishing solution and adjusting the alkali concentration in the weakly basic aqueous solution to polish the front surface of the silicon wafer by adjusting the alkali concentration such that the haze value for the final-polished front surface of the silicon wafer is lower than the haze value for the finish-polished front surface of the silicon wafer.

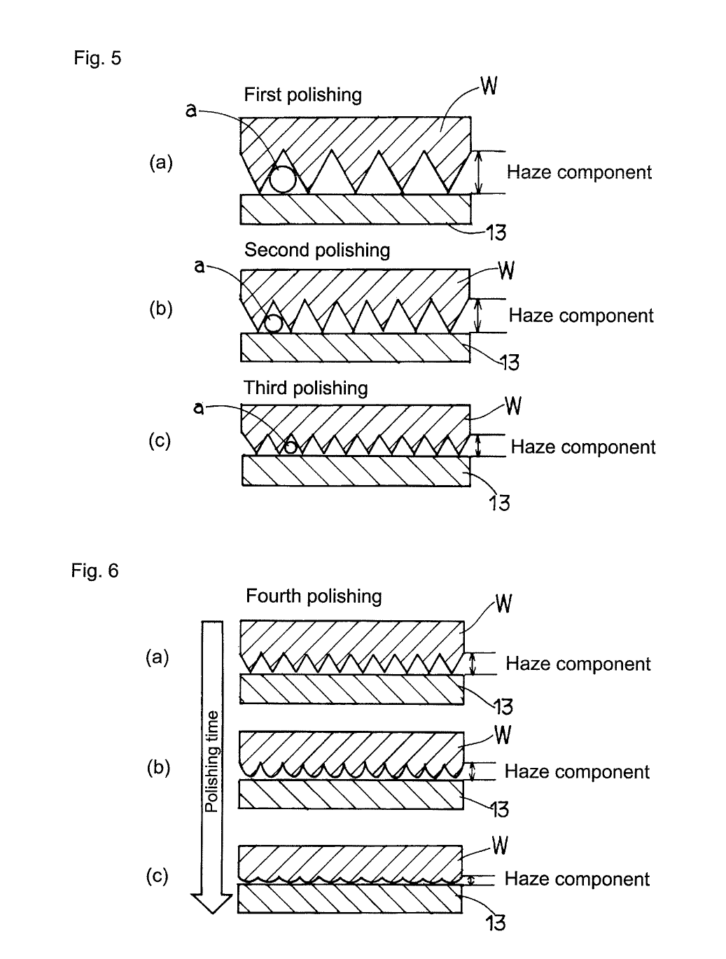

Moreover, as shown in FIGS. 5(a) to 5(c), in addition to first polishing (rough polishing), second polishing and third polishing (finish polishing) performed using a polishing cloth 13 are abrasive grain polishings in which free abrasive grains a are contained in a polishing solution. Thus, the haze level after polishing is dependent on the particle size of the free abrasive grains a during finish polishing. Accordingly, as long as the size of the abrasive grains does not change even during prolonged polishing, a reduction in the haze level on a polished surface of a silicon wafer W cannot be achieved. However, as shown in FIGS. 6(a) to 6(c), a fourth polishing (final polishing) is a non-abrasive grain polishing using an alkali etching action from a weakly basic aqueous solution that does not contain the free abrasive grains a. Therefore, a haze value for the haze level on a final-polished surface of the silicon wafer W can be reduced even lower than the finish-polished surface the longer the silicon wafer W is polished.

Herein, the weakly basic aqueous solution has a low degree of ionization when a weakly basic substance is made into an aqueous solution. Examples of the weakly basic aqueous solution include an ammonia solution, a mixed aqueous solution of ammonia and ammonium bicarbonate, an aqueous solution of tetramethylammonium hydroxide, and an aqueous solution of tetraethylammonium hydroxide. When ammonia is made into an aqueous solution, for example, ammonium hydroxide results, and a portion thereof ionizes into ammonium ions and hydroxide ions, thus demonstrating basic properties. Only a small portion of the ammonium hydroxide ionizes, and the remainder is present in the water as ammonium hydroxide. Accordingly, there are few effective hydroxide ions as compared to a case where a strongly basic substance is used, and thus the etching speed is comparatively leisurely. In addition, the weakly basic substance can be easily obtained at a high level of purity with extremely few metallic ions. However, even when, for example, a process is performed in which the silicon wafer is immersed in an etching bath filled with the weakly basic aqueous solution and the front surface thereof is alkali etched, almost no action is achieved to selectively etch protrusions in unevenness, which are components of haze on the front surface of the silicon wafer.

The haze level can be reduced by using a weakly basic aqueous solution adjusted to a low alkali concentration as the polishing solution and performing a polishing process on the front surface of the wafer. This means that due to rotation of at least one of the silicon wafer and a polishing platen during the final polishing process, the weakly basic aqueous solution with the low alkali concentration is made to flow in a radial direction of the wafer; the etching action in a centrifugal direction (radial direction of the wafer) is prioritized over the etching action in the depth direction of the silicon wafer; and the protrusions in the unevenness, which are components of haze on the front surface of the silicon wafer, are selectively etched, reducing the haze level. Meanwhile, in a case where a strongly basic aqueous solution is used that has an ionization rate for NaOH, KOH, and the like that is close to 1, when these strongly basic substances are made into an aqueous solution, the solution ionizes completely into sodium ions (potassium ions) and hydroxide ions. Therefore, the etching action on the silicon is too strong and no action is achieved to selectively etch the protrusions in the unevenness, which are components of haze on the front surface of the silicon wafer. The entirety of the unevenness is equally and uniformly etched and the haze level on the final-polished surface may deteriorate even further than the haze level on the finish-polished surface. In addition, there is a negative circumstance in which residual metallic ions are present as impurities.

In the method for polishing the silicon wafer in the present invention, by adding a water-soluble polymer to the final polishing solution, the haze level on the front surface of the silicon wafer after final polishing can be further reduced. Specifically, the water-soluble polymer in the final polishing solution bonds to the front surface of the silicon wafer and has an effect of inhibiting the etching reaction. Therefore, the water-soluble polymer bonded to the protrusions in the unevenness, which are components of haze on the front surface of the silicon wafer, is wiped away by contact with the polishing cloth, thus promoting the alkali etching of the protrusions. Meanwhile, the water-soluble polymer bonds to and accumulates within the depressions in the unevenness, which are components of haze on the front surface of the silicon wafer, thus inhibiting the promotion of the alkali etching on the depressions and selectively promoting the etching action for the protrusions.

A monocrystalline silicon wafer and a polycrystalline silicon wafer, for example, may be employed as the silicon wafer to be polished. An epitaxial silicon wafer and an SOI silicon wafer may also be used. The diameter of the silicon wafer may be, for example, 100 mm, 125 mm, 150 mm, 200 mm, 300 mm, and 450 mm.

The surface of the silicon wafer to be rough polished may be the front surface, the rear surface, or both. In the rough polishing, a hard polishing cloth made of polyurethane, for example, is used to polish the silicon wafer while supplying a rough polishing solution containing free abrasive grains having an average particle size of 30-100 nm (e.g., colloidal silica, diamond abrasive grains, alumina abrasive grains) to the polishing cloth. Variations in thickness of the silicon wafer are thus flattened and made smaller after polishing. In the rough polishing operation, polishing may be performed while changing the type of polishing cloth and the size of the free abrasive grains contained in the rough polishing solution, and while dividing the polishing amount of the polished surface of the silicon wafer into two or three stages, for example. An alkaline aqueous solution in which the pH has been adjusted to a pH of 8-13 is preferably used as the rough polishing solution. The alkaline agent is preferably an alkaline aqueous solution to which a basic ammonium salt, a basic potassium salt, a basic sodium salt or the like has been added; an alkaline carbonate aqueous solution; or an alkaline aqueous solution to which amine has been added. Moreover, the rough polishing may be a non-abrasive grain polishing method using a rough polishing solution composed of a highly concentrated alkaline aqueous solution that does not contain free abrasive grains.

In a case where the front and rear surfaces of the wafer are rough polished, polishing is preferably performed using a double surface polishing device that includes a carrier plate accommodating the silicon wafer and an upper platen and a lower platen to which the polishing cloth has been adhered, on both sides of the carrier plate. A sun gear (epicyclic gear) system or a non-sun gear system which causes circular motion without inducing rotation in the carrier plate may be used as the double surface polishing device. A high degree of flatness can thus be achieved for the rear surface of the wafer, and not only the front surface of the wafer, in a single polishing process.

In the finish polishing, an alkaline aqueous solution containing free abrasive grains can be used as the finish polishing solution. For example, finish polishing solution can be used in which free abrasive grains such as colloidal silica (abrasive grains), diamond abrasive grains, and alumina abrasive grains are mixed into the alkaline aqueous solution. Thereby, the polished surface of the silicon wafer is polished by a mechanical abrasive action chiefly due to the free abrasive grains and by a chemical action due to the alkali. The average particle size of the free abrasive grains added to the alkaline aqueous solution used in the finish polishing solution may be selected within a range of particle sizes where the abrasive grains do not aggregate so as to not cause the development of processing-induced defects such as micro-scratches. Grains having an average particle size of 10-50 nm are preferred. When the average particle size is less than 10 nm, the dispersability of the abrasive grains in the polishing solution decreases and the abrasive grains aggregate, which may give rise to processing-induced defects such as micro-scratches on the front surface of the silicon wafer. When greater than 50 nm, the haze value for the front surface of the silicon wafer after finish polishing greatly deteriorates and even when non-abrasive grain polishing, in which the chief component is a weakly basic aqueous solution that does not contain abrasive grains (such as an ammonia aqueous solution), is performed thereafter, reducing the haze level to a required level is difficult. The average particle size is measured with a BET method.

The alkaline aqueous solution used is preferably an alkaline aqueous solution in which the pH is adjusted to 8-13, similar to the rough polishing solution. Examples of the alkaline agent include an alkaline aqueous solution to which any of a basic ammonium salt, a basic potassium salt, a basic sodium salt, or the like has been added; an alkaline carbonate aqueous solution; or an alkaline aqueous solution to which amine has been added. Moreover, the finish polishing differs from polishing in which a degree of flatness of the silicon wafer is adjusted, as in rough polishing. Finish polishing is performed with the intent of remedying minute undulations and the haze level in the front surface of the wafer. When the front surface of the wafer is evaluated under local conditions in a surface detection device (DWO mode in an SP2, manufactured by KLA-Tencor Corporation) after cleaning (SC-1 cleaning) the finish-polished silicon wafer, a silicon wafer having a haze level of 0.03-0.2 ppm is manufactured.

A pliant polishing cloth is appropriate as the polishing cloth used in finish polishing, unlike the hard polyurethane polishing cloth, for example, used in rough polishing. Specifically, a velour-type or suede-type polishing cloth may be used. The velour-type polishing cloth is a single-layer structure known as a non-woven fabric and is a porous sheet-shaped material having a three-dimensional structure. The suede-type polishing cloth is known as artificial leather for use in industrial materials. The suede-type polishing cloth is configured with a substrate layer, made of non-woven fabric having a three-dimensional structure and formed with synthetic fibers and a special synthetic rubber, and a surface layer, in which a plurality of fine pores (holes) are formed in a polymer resin having excellent abrasion resistance such as polyester resins, polyether resins, and polycarbonate resins.

A polishing solution chiefly composed of a weakly basic aqueous solution not containing free abrasive grains may be used as the final polishing solution. Herein, “a weakly basic aqueous solution not containing free abrasive grains” means that free abrasive grains such as colloidal silica, diamond abrasive grains, and alumina abrasive grains are not mixed into the weakly basic aqueous solution which is the chief component of the final polishing solution. Thereby, the final-polished surface of the silicon wafer is polished by a chemical action and the development of processing damage due to mechanical action, as in finish polishing using free abrasive grains, can be avoided. Moreover, because the final polishing does not use free abrasive grains, the development of processing-induced defects such as micro-scratches arising from the aggregation of abrasive grains can be reduced.

The alkali concentration (content amount of the alkaline agent) in the weakly basic aqueous solution used in the final polishing solution is adjusted such that a haze value for the final-polished surface is lower than the haze value for the finish-polished surface of the silicon wafer. When the alkali concentration is greater than a concentration value at which the haze value of the finish-polished surface of the silicon wafer is achieved, the etching action on the front surface of the silicon wafer increases excessively and the haze level on the final-polished surface deteriorates further than the finish-polished surface.

In a case where the weakly basic aqueous solution of the final polishing solution is ammonia water, the alkali concentration of the weakly basic aqueous solution is preferably adjusted to a range of 0.1-1000 ppm. At less than 0.1 ppm, the remedying effects on the haze level on the finish-polished surface are slight. At greater than 1000 ppm, surface roughness is likely to develop on the final-polished surface of the silicon wafer due to an excessive alkali etching reaction. In the range of 0.1-1000 ppm, the haze components of the finish-polished surface of the silicon wafer (the unevenness on the wafer surface that occurs due to abrasive grain polishing) may be reduced. Moreover, when ammonia water is used, the haze value tends to deteriorate after the alkali concentration surpasses 500 ppm. Therefore, from the perspective of achieving an efficacious remedying effect on the haze value, adjusting the alkali concentration to a range of 10-500 ppm is particularly preferable.

In a case where the weakly basic aqueous solution of the final polishing solution is a tetramethylammonium hydroxide solution, the alkali concentration of the weakly basic aqueous solution is preferably adjusted to a range of 0.1-100 ppm. At less than 0.1 ppm, the remedying effects on the haze level on the finish-polished surface are slight. At greater than 100 ppm, surface roughness is likely to arise in the final-polished surface of the silicon wafer due to an excessive alkali etching reaction. In a range of 0.1-100 ppm, the haze components (unevenness on the wafer surface that occurs due to abrasive grain polishing) of the finish-polished surface of the silicon wafer can be reduced. Moreover, when tetramethylammonium hydroxide solution is used, the haze value tends to deteriorate when the alkali concentration surpasses 50 ppm. Therefore, from the perspective of achieving an efficacious remedying effect on the haze value, adjusting the alkali concentration to a range of 1-50 ppm is particularly preferable.

In a case where the weakly basic aqueous solution of the final polishing solution is a mixed aqueous solution of ammonia and ammonium bicarbonate, the alkali concentration of the weakly basic aqueous solution is preferably adjusted to a range of 0.1-500 ppm. At less than 0.1 ppm, the remedying effects on the haze level on the finish-polished surface are slight. At greater than 500 ppm, surface roughness is likely to arise in the final-polished surface of the silicon wafer due to an excessive alkali etching reaction. Moreover, when the mixed aqueous solution of ammonia and ammonium bicarbonate is used, the haze value tends to deteriorate after the alkali concentration surpasses 100 ppm. Therefore, from the perspective of achieving an efficacious remedying effect on the haze value, adjusting the alkali concentration to a range of 10-100 ppm is particularly preferable.

The pliant polishing cloth used in the finish polishing may be used as the polishing cloth for use in the final polishing. The suede-type polishing cloth is particularly preferred. The reason for this is not clear. However, the inventors of the present invention have identified that the remedying effects on the haze level are greater with the suede-type polishing cloth than with the velour-type polishing cloth. Specifically, a polishing cloth having a Shore C hardness of 40-80 and an elastic compression modulus of 60-100% as defined by JIS K 6253-1997/ISO 7619 is appropriate.

The final polishing (as in the rough polishing and the finish polishing) is performed by rotating the silicon wafer and the polishing cloth relative to each other. “Rotating relative to each other” means rotating the silicon wafer, rotating the polishing cloth, or rotating both the silicon wafer and the polishing cloth. Rotation directions of the silicon wafer and the polishing cloth are at the user's discretion. For example, when both the silicon wafer and the polishing cloth are rotated, the rotation direction of the two may be the same or different. During final polishing, an amount of polishing for the finish-polished surface of the silicon wafer is preferably more than 0 Å and 80 Å or less. Specifically, the final polishing attempts to selectively remove only the protrusions in the unevenness, which are components of haze on the front surface of the finish-polished silicon wafer. Therefore, the protrusions may be removed at an extremely slight polishing amount of more than 0 Å and 80 Å or less to achieve a sufficient haze remedying effect. The polishing time may also be set so as to achieve this polishing amount. A polishing time of ten minutes or less at the most is sufficient. Thereby, the haze value may be made smaller than the haze value of the finish-polished surface.

In the final polishing of the silicon wafer (as in the rough polishing and the finish polishing), a single wafer type polishing device may be used and a batch-type polishing device simultaneously polishing a plurality of silicon wafers may be used. In addition, single surface polishing of only the front surface and double surface polishing in which the front and rear surfaces of the wafer are polished simultaneously may be used. Moreover, the polishing device for use in the final polishing may continuously employ the polishing device for use in the finish polishing and change only the polishing solution. However, the free abrasive grains used in the finish polishing remain in the front surface of the polishing cloth, thus necessitating a cleaning operation to remove them and work to change the polishing solution. Therefore, using a polishing device exclusively for the final polishing that is different from the polishing device for the finish polishing is particularly preferred.

A final polishing solution to which a water-soluble polymer has been added is preferred. Thereby, the haze level on the silicon wafer after final polishing can be further reduced. One kind or a plurality of kinds from among a non-ionic polymer and a monomer, or one kind or a plurality of kinds from among an anionic polymer and a monomer may be used as the water-soluble polymer. Hydroxyethylcellulose (HEC) and polyethylene glycol (PEG) are preferably used as the water-soluble polymer. In particular, highly pure hydroxyethylcellulose may be obtained comparatively easily and readily forms a polymer film on the front surface of the wafer. Therefore, an inhibiting effect on alkali etching reactions is characteristically large in hydroxyethylcellulose. However, of the various kinds of water-soluble polymers, a water-soluble polymer that promotes etching of the silicon wafer by the weakly basic aqueous solution is inappropriate. Only one kind of water-soluble polymer may be used, or a plurality of kinds may be used.

Instead of the water-soluble polymer, a surfactant or a fatty alcohol may be used. Polyoxyethylene alkyl ether, for example, may be used as the surfactant. A polyvinyl alcohol, for example, may be used as the fatty alcohol. The concentration of the water-soluble polymer in the final polishing solution may be set to a range of 0.1-1000 ppm, and 10-100 ppm is particularly preferred. When hydroxyethylcellulose is used as the water-soluble polymer, the additive rate is preferably 10-100 ppm. When too much is added, polishing may become impossible to perform.

### Embodiment 1

A plurality of crystalline orientation (100) silicon wafers having a diameter of 300 mm and which had been lapped and chamfered were prepared. A first polishing corresponding to rough polishing, a second polishing corresponding to an early stage of finish polishing, a third polishing corresponding to a later stage of finish polishing, and a fourth polishing corresponding to final polishing were conducted on the silicon wafers (flowchart of FIG. 1).

In the first polishing operation, a non-sun gear-type double surface polishing device was used to perform the first polishing using a first polishing solution to simultaneously polish a front and rear surface of the silicon wafer. The first polishing solution used a KOH aqueous solution to which colloidal silica granules (free abrasive grains) having an average particle size of 70 nm had been added at 5% by weight to rough polish the front and rear surfaces of the silicon wafer. A polishing amount at this stage was 10 μm per surface.

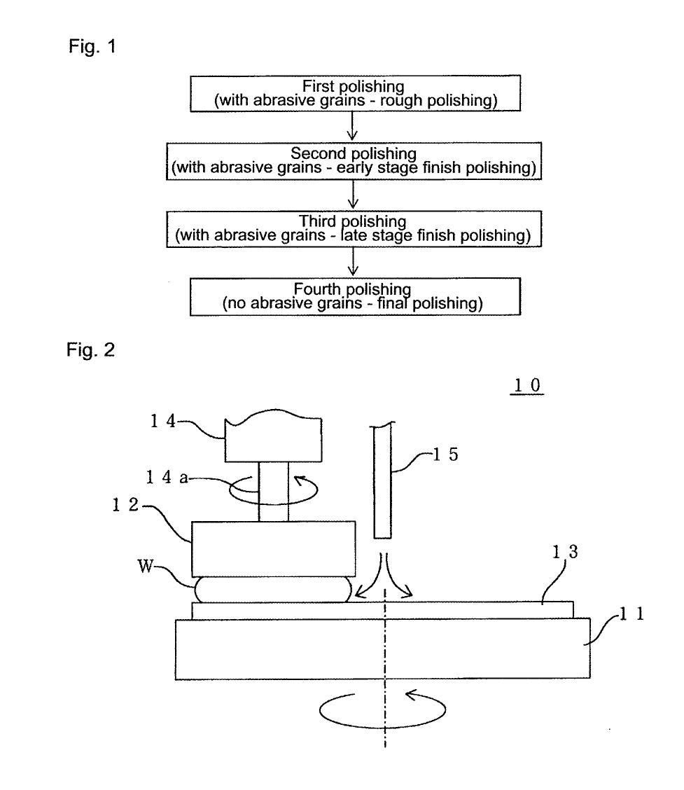

Next, second polishing was conducted on the first-polished front surface of a silicon wafer W using a single surface mirror polishing device while supplying a second polishing solution that contained free abrasive grains. As shown in FIG. 2, a single surface mirror polishing device 10 includes a polishing platen 11 and a polishing head 12 disposed above the polishing platen 11. A polishing cloth 13 made of a hard foam urethane pad is adhered to an upper surface of the polishing platen 11. The polishing head 12 is fixed to a rotation shaft 14a on a head driver 14 and has one silicon wafer W vacuum-attached to a lower surface of the polishing head 12. In addition, a slurry nozzle 15 is provided above a central portion of the polishing platen 11, supplying the second polishing solution to the polishing cloth 13. The second polishing solution used a polishing solution in which colloidal silica granules having an average particle size of 70 nm had been added at 0.5% by weight to 0.08% by weight of KOH aqueous solution.

During the second polishing, via the rotation shaft 14a, the polishing head 12 was gradually lowered while being rotated by the head driver 14, pressing the silicon wafer W against the polishing cloth 13. In this state, the front surface of the silicon wafer W was second polished while the second polishing solution was supplied to the polishing cloth 13 from the slurry nozzle 15. Thereby, the early stage of finish polishing for a polishing amount of 0.6 μm was conducted on the first-polished front surface of the silicon wafer W.

Next, the second-polished front surface of the silicon wafer W was third polished. Specifically, using the single surface mirror polishing device 10 used in the second polishing, the front surface of the silicon wafer W was third polished while supplying a third polishing solution to the polishing cloth 13. The third polishing solution was a polishing solution in which colloidal silica granules having an average particle size of 35 nm had been added at 0.5% by weight to 0.08% by weight of KOH aqueous solution. Thereby, the later stage of finish polishing for a polishing amount of 0.04 μm was conducted on the second-polished front surface of the silicon wafer W. Next, SC1 cleaning with a predetermined SC1 cleaning liquid was conducted on the third-polished silicon wafer W. Thereafter, a haze level on the front surface of the wafer was measured. The measurement results gave a haze value of 0.077 ppm for the front surface of the silicon wafer W. An SP2 manufactured by KLA-Tencor Corporation was used as a surface detection device in the measurement of the haze value. The measurement was conducted using a DWO mode (Dark Field Wide Oblique mode) of the SP2. Moreover, in the present embodiment, an example was given of conducting the finish polishing in two stages of second polishing and third polishing. However, a single stage polishing process may conduct the second polishing with the conditions of the third polishing.

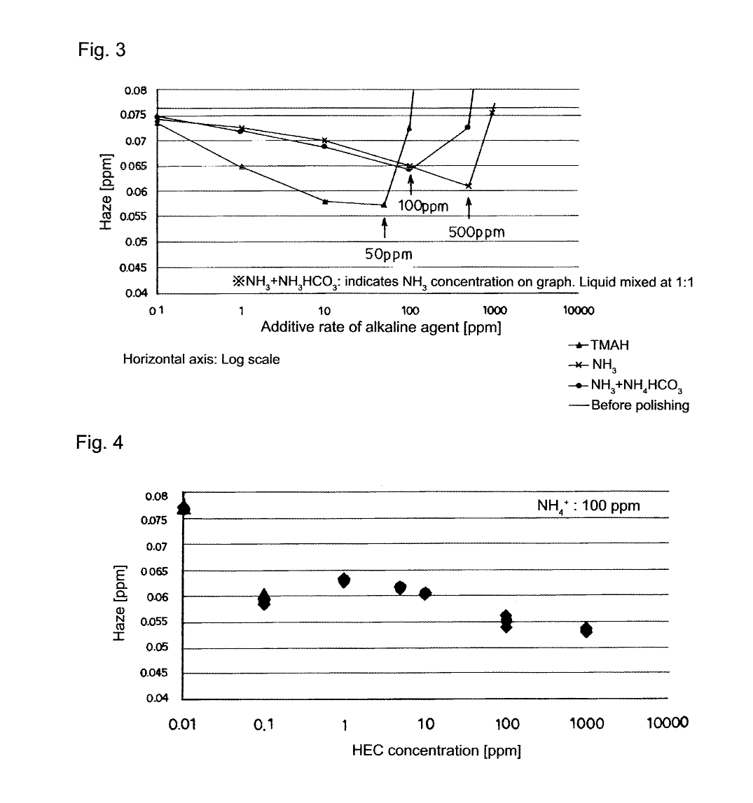

Next, the front surface of the silicon wafer W after third polishing was fourth polished (final polished) using a fourth polishing solution (final polishing solution) not containing free abrasive grains. Specifically, using the single surface mirror polishing device 10 used in the first through third polishing, a polishing cloth 13 made of suede having a Shore C hardness of 64 and an elastic compression modulus of 63% as defined by JIS K 6253-1997/ISO 7619 (Ciegal, made by Chiyoda Co., Ltd.) was used. During fourth polishing, the front surface of the silicon wafer W was fourth polished while supplying the fourth polishing solution (composed of ammonia water not containing free abrasive grains) to the polishing cloth 13 at 0.4 liter/minute under polishing conditions where the polishing platen 11 and the polishing head 12 had a rotation speed of 50 rpm (rotating in opposite directions), the polishing pressure was 100 g/cm², the polishing time was three minutes, and the concentration was changed to 0.1-1000 ppm. The results are shown in the graph of FIG. 3. The graph of FIG. 3 shows the results of a test to verify a difference in the additive rate of the alkaline agent (alkali concentration) necessary for the haze value of the front surface of the silicon wafer W after final polishing to reach the haze value of the finish-polished surface (0.077 ppm). The surface detection device (DWO mode in the SP2 manufactured by KLA-Tencor Corporation) was used to measure the haze value. In addition, before measuring the haze value for the final-polished surface, the front surface of the silicon wafer W was cleaned with a predetermined SC1 cleaning liquid.

As made clear by the graph in FIG. 3, when the final polishing solution is ammonia water, the additive rate of ammonia necessary for the haze value of the front surface of the wafer to reach 0.077 ppm is approximately 1000 ppm. For example, when the additive rate of ammonia added to the ammonia water of the final polishing solution is 100 ppm, the haze value of the final-polished surface was 0.065 ppm.

### Embodiment 2

Next, similarly making reference to the graph of FIG. 3, a method for polishing a silicon wafer according to a second embodiment of the present invention is described. In the second embodiment, an aqueous solution of tetramethylammonium hydroxide (TMAH) was used as the weakly basic aqueous solution instead of the ammonia water of Embodiment 1 to perform fourth polishing of the front surface of the silicon wafer W after third polishing under the same conditions as Embodiment 1. The results are, again, shown in FIG. 3. As made clear by the graph in FIG. 3, when the final polishing solution is the aqueous solution of tetramethylammonium hydroxide (TMAH), with the additive rate in a range of 0.1-50 ppm, the haze level on the front surface of the silicon wafer W decreased as the additive rate increased. Meanwhile, at the point that the additive rate of tetramethylammonium hydroxide surpassed 50 ppm, as the additive rate increased, the haze level on the front surface of the wafer deteriorated. When the additive rate reached approximately 100 ppm, the haze level reached the haze value of the finish-polished surface. Other configurations, actions, and effects are similar to Embodiment 1, and thus their description is omitted.

### Embodiment 3

Next, similarly making reference to the graph of FIG. 3, a method for polishing a silicon wafer according to a third embodiment of the present invention is described. In the third embodiment, a mixed aqueous solution of ammonia and ammonium bicarbonate (NH₄HCO₃) was used as the weakly basic aqueous solution instead of the ammonia water of Embodiment 1 to perform fourth polishing of the front surface of the silicon wafer W after third polishing under the same conditions as Embodiment 1. The results are, again, shown in FIG. 3. Moreover, the mixture ratio of ammonia and ammonium bicarbonate is 1:1 by weight. As made clear by the graph in FIG. 3, when the final polishing solution is the mixed aqueous solution of ammonia and ammonium bicarbonate (NH₄HCO₃), when the additive rate of ammonia and ammonium bicarbonate was in a range of 0.1-100 ppm, the haze level on the front surface of the silicon wafer decreased as the additive rate of these alkaline agents increased. Meanwhile, at the point that the additive rate of the mixture of ammonia and ammonium bicarbonate surpassed 100 ppm, the haze level on the front surface of the wafer also began to deteriorate as the additive rate increased. When the additive rate reached approximately 500 ppm, the haze level reached the haze value of the finish-polished surface. Other configurations, actions, and effects are similar to Embodiment 1, and thus their description is omitted.

### Embodiment 4

Next, with reference to the graph of FIG. 4, a method for polishing a silicon wafer according to a fourth embodiment of the present invention is described. Because the effectiveness of the addition of a water-soluble polymer in the final polishing is recognized, a fourth polishing solution composed of ammonia water at an ammonia (NH₄⁺) concentration of 100 ppm and not containing free abrasive grains was used as a chief component of the final polishing solution for fourth polishing (final polishing). Hydroxyethylcellulose (HEC; a water-soluble polymer) was added thereto and, using the silicon wafer W that was finish polished under the conditions of the first to third polishing performed in Embodiment 1, a polishing experiment was performed three times, changing the additive rate of hydroxyethylcellulose (first time: ▴; second time: ; third time: ♦). Other conditions of the fourth polishing were the same as Embodiment 1. The additive rate of hydroxyethylcellulose in the final polishing solution and the haze value of the final-polished surface of the silicon wafer W were measured in the DWO mode using the surface detection device (the SP2 manufactured by KLA-Tencor Corporation), and the results are shown in the graph of FIG. 4. As made clear by the graph of FIG. 4, when the additive rate of the hydroxyethylcellulose is 0.1-1000 ppm, the haze level on the silicon wafer W is seen to decrease greatly. Other configurations, actions, and effects are similar to Embodiment 1, and thus their description is omitted.

### INDUSTRIAL APPLICABILITY

The present invention is useful as a method for manufacturing a silicon wafer having a decreased surface roughness for use in a semiconductor device.

### DESCRIPTION OF REFERENCE NUMERALS

13 polishing cloth,
W silicon wafer,
a free abrasive grains.

1. A method for polishing a silicon wafer, comprising:
rotating a polishing cloth and the silicon wafer relative to each other while supplying a finish polishing solution containing free abrasive grains to the polishing cloth to finish polish at least a front surface of the front and rear surfaces of the silicon wafer; and
after the finish polishing, rotating the polishing cloth and the silicon wafer relative to each other while supplying a final polishing solution chiefly composed of a weakly basic aqueous solution not containing free abrasive grains to the polishing cloth to final polish a surface of the silicon wafer that has been finish polished, wherein
an alkali concentration of the weakly basic aqueous solution is adjusted in the final polishing solution such that a haze value of the final-polished surface of the silicon wafer is lower than the haze value of the finish-polished surface of the silicon wafer.

2. The method for polishing the silicon wafer according to claim 1, wherein
the alkali concentration of the weakly basic aqueous solution in the final polishing solution is:
0.1 to 1000 ppm when the weakly basic aqueous solution is ammonia water;
0.1 to 100 ppm when the weakly basic aqueous solution is an aqueous solution of tetramethylammonium hydroxide; and
0.1 to 500 ppm when the weakly basic aqueous solution is a mixed aqueous solution of ammonia and ammonium bicarbonate.

3. The method for polishing the silicon wafer according to claim 1, wherein a water-soluble polymer is added to the final polishing solution.

4. The method for polishing the silicon wafer according to claim 3, wherein the water-soluble polymer is one kind or several kinds among a non-ionic polymer and a monomer, or one kind or several kinds among an anionic polymer and a monomer.

5. The method for polishing the silicon wafer according to claim 4, wherein the water-soluble polymer is hydroxyethylcellulose.

6. The method for polishing the silicon wafer according to claim 1, wherein the polishing cloth used in the final polishing is of a suede type.

7. The method for polishing the silicon wafer according to claim 2, wherein a water-soluble polymer is added to the final polishing solution.

8. The method for polishing the silicon wafer according to claim 7, wherein the water-soluble polymer is one kind or several kinds among a non-ionic polymer and a monomer, or one kind or several kinds among an anionic polymer and a monomer.

9. The method for polishing the silicon wafer according to claim 8, wherein the water-soluble polymer is hydroxyethylcellulose.
